(19) United States
(12) Patent Application Publication
(10) Pub. No.: US 2006/0151206 A1
(43) Pub. Date: Jul. 13, 2006

(54) Semiconductor device and manufacturing method therefor

(75) Inventors: Tomoyo Maruyama, Kitakatsuragi-gun (JP); Yuji Yano, Tenri-shi (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/324,635

(22) Filed: Jan. 4, 2006

(30) Foreign Application Priority Data
Jan. 13, 2005 (JP) 2005-006862

(51) Int. Cl. H05K 1/16

(52) U.S. Cl. 174/260

(57) ABSTRACT

A semiconductor device of the present invention includes a semiconductor elements on a circuit board of the semiconductor device, interposing an adhesive material between the semiconductor element and the circuit board. Further, a connection use circuit board including an external terminal connecting portion is mounted on an upper surface of the semiconductor element, interposing an adhesive material between the connection use circuit board and the semiconductor element, and a lower surface of the connection use circuit board and the upper surface of the circuit board are connected with each other via an electrically conductive terminal. A space between the circuit board and the connection use circuit board is sealed with sealing resin. With this configuration, it is possible to realize a small and thin semiconductor device which allows for (i) less restricted arrangement of an external connection terminal, which connects the semiconductor device with a semiconductor device or an electronic component laminated on an upper stage, and (ii) an improvement in a packaging density, and which is excellent in a heat radiation characteristic.

This Nonprovisional application claims priority under 35 U.S.C. § 119(a) on Patent Application No. 006862/2005 filed in Japan on Jan. 13, 2005, the entire contents of which are hereby incorporated by reference.

### FIELD OF THE INVENTION

The present invention relates to a semiconductor device including a semiconductor element; a lamination of semiconductor device in which a plurality of semiconductor devices are laminated; and a manufacturing method for the semiconductor device and the lamination.

### BACKGROUND OF THE INVENTION

A technique for more densely packaging semiconductor devices has been increasingly demanded with the development in smaller, lighter and more sophisticated electronic devices. In response to such a demand, a semiconductor device including a plurality of semiconductor elements was invented. This invention allows an increase in a packaging density of semiconductor element per unit area of a mounting board.

However, in terms of manufacturing technology and product reliability, there is a limit in packaging a number of semiconductor elements in a single semiconductor device.

When a number of semiconductor elements or various kinds of semiconductor elements are packaged in a single semiconductor device, a density of wiring on a circuit board will increase. More specifically, packaging of a number of semiconductor elements or various kinds of semiconductor elements in a single semiconductor device necessitates: (i) an increase in the number of wiring layers of the circuit board; and/or (ii) an increase in a density of connecting portions connecting, by using a bonding technique such as wire bonding or a flip-chip bonding, the semiconductor element with the circuit board. Consequently, the electrical connection between the circuit board and the semiconductor element becomes complicated.

Further, when various kinds of semiconductor elements are packaged in a single semiconductor device, the semiconductor device is highly specialized for a specific purpose, and becomes less versatile.

In order to solve the problem, Japanese unexamined patent publication No. 4-280695/1992 (Tokukaihei 4-280695; published on Oct. 6, 1992; Hereinafter, Patent document 1) discloses the following technology. Namely, instead of packaging all of necessary semiconductor elements in a single semiconductor device, several semiconductor elements are packaged in the single semiconductor device, and an identical semiconductor device or another semiconductor device is laminated on the semiconductor device, thereby forming a lamination which serves as one semiconductor device. This technology, while maintaining the required packaging density, solves the problem of manufacturing method and the reliability, and realizes a versatile semiconductor device.

FIG. 10 is a cross sectional view of the semiconductor device disclosed in Patent document 1. In the conventional technology disclosed in Patent document 1, a circuit board 102 having a semiconductor element 101 is provided with a through hole 103, thereby realizing an electrical connection between an upper surface and a lower surface of the circuit board 102. Further, on the upper surface of the circuit board 102 (i.e., the surface having thereon the semiconductor element 101), the semiconductor element 101 is connected with a part of connection pad on the circuit board 102, by using a wire-bonding technique. The semiconductor element 101 and bonding wire are sealed with sealing resin 105. The sealing resin 105 does not seal the entire upper surface of the circuit board 102, so that an external terminal connecting portion 104 is exposed.

FIG. 11 is a cross sectional view illustrating a lamination in which a plurality of the semiconductor devices illustrated in FIG. 10 are laminated. In this lamination, the plurality of the semiconductor devices of FIG. 10 are laminated, and respective circuit boards 102 are connected with each other by using an electric conductor 106. That is, the electric conductor 106 connects the external terminal connecting portion 104 exposed on the upper surface of the lower semiconductor device with a back surface electrode pad exposed on a lower surface of the upper semiconductor device, so as to provide an electrical connection between the plurality of the semiconductor devices laminated. The back surface electrode pad and the external terminal connecting portion 104 are electrically connected with each other via the through hole 103.

The invention of Patent document 1 necessitates not only wiring for connecting the semiconductor element 101 with the external terminal connecting portion 104, but also wiring for electrically connecting the semiconductor device with the other semiconductor device laminated on top or at the bottom. This result in complicated wiring of the circuit board 102, which consequently increases the size of the circuit board 102. Accordingly, a planar dimension of the semiconductor device surpasses, by a considerable amount, that of the semiconductor element 101.

For example, Japanese unexamined patent publication No. 2004-172157 (Tokukai 2004-172157; published on Jun. 17, 2004; Hereinafter, Patent document 2) discloses the following technology for solving the above problem. FIG. 12 is a cross sectional view of a semiconductor device disclosed in Patent document 2.

In the conventional technology disclosed in Patent document 2, a semiconductor element 111 is provided on a circuit board 112, and is electrically connected with the circuit board 112 via wiring 113. Further, a connection use circuit board 114 is provided above the semiconductor element 111, interposing therebetween an adhesive material 115. The connection use circuit board 114 is used in a case of laminating another semiconductor device on the semiconductor device of FIG. 12, and is for use in electrically connecting the other semiconductor device with the semiconductor device of FIG. 12. Such a connection use circuit board 114 is provided with an external terminal connecting portion 116, and is connected with the circuit board 112 via wiring 117.

Further, the wiring 113 and the wiring 117 are sealed with sealing resin 118. Further, an external connection terminal 119 is provided at a lower surface of the circuit board 112.

With the semiconductor device of FIG. 12, it is possible to provide the connection use circuit board 114 with the wiring for electrically connecting with the above-laminated semiconductor device, instead of providing such wiring on the circuit board 112. This prevents the wiring of the circuit board 112 and the connection use circuit board 114 from becoming complicated. This is advantageous in: restraining an increase in the planar dimension of the both circuit boards; and downsizing the semiconductor device.

However, the conventional technology disclosed in Patent document 2 adopts, as a connecting method, a wire bonding technique which uses the wiring 117 for connecting the connection use circuit board 114 with the circuit board 112. Accordingly, a loop-height of the wiring 117 and a height of the sealing resin 118 for sealing the wiring 117 are added to the connection use circuit board 114. This causes an increase in the total height of the semiconductor device; i.e., the thickness of the semiconductor device.

Further, in the semiconductor device of FIG. 12, the semiconductor element 111 and the circuit board 112 are connected with each other by using a wire bonding technique. Therefore, the connection use circuit board 114 is limited to one whose planar dimension is smaller than that of the semiconductor element 111 which is located below the connection use circuit board 114.

Additionally, since the connection use circuit board 114 and the circuit board 112 are connected with each other by using the wiring 117, a plane region of the connection use circuit board 114 to which the external terminal connecting portion 116 is provided is reduced. This limits the number and a pitch of the external terminal connecting portions 116 provided on the connection use circuit board 114, and causes difficulties in increasing the packaging density.

Further, Patent document 2 discloses that the semiconductor device of Patent document 2 allows lamination of plural semiconductor elements on the circuit board 112. However, the upper semiconductor elements are limited to those whose respective planar dimensions are smaller than the planer dimensions of the respective lower semiconductor elements. Accordingly, in the case of laminating the plurality of semiconductor elements on the circuit board 112, the area of the connection circuit board 114 is reduced with an increase in the number of the semiconductor elements being laminated. This is considerably disadvantageous in terms of packaging density.

Further, in a case where another semiconductor device is provided on the connection use circuit board 114, a heat generated in the upper semiconductor device due to its operation is mainly transferred to the semiconductor element 111, via the connection use circuit board 114 and the adhesive material 115. This heat is further transferred from the semiconductor element 111 to a mounting board, via the circuit board 112 and the external connection terminal 119, and is radiated.

The adhesive material 115 is made thin, and therefore easily transfers the heat from the connection use circuit board 114 to the semiconductor element 111. Further, the adhesive material is also interposed between the semiconductor element 111 and the circuit board 112. This makes it relatively easy to transfer the heat from the circuit board 114 to the mounting board.

However, if the semiconductor element 111 also generates a heat due to its operation, the heat generated in the semiconductor element 111 causes difficulty in transferring, to the connection use circuit board 114, the heat generated by the operation of the semiconductor device laminated above the connection use circuit board 114. This is attributed to a characteristic of heat, where an ease at which heat is transferred is proportional to a temperature difference.

Further, the wiring 117, which is another path connecting the connection use circuit board 114 with the circuit board 112, can only transfer a limited amount of heat. Accordingly, the wiring 117 does not contribute much to the heat radiation.

In conclusion, in the case of laminating the semiconductor device on top of the semiconductor device disclosed in Patent document 2, a heat radiating characteristic of the upper semiconductor device is deteriorated, in the case where both of the semiconductor devices generate a heat, due to operations of the respective semiconductor elements.

### SUMMARY OF THE INVENTION

An object of the present invention is to realize a small and thin semiconductor device which allows for (i) less restricted arrangement of an external connection terminal, which connects the semiconductor device with a semiconductor device or an electronic component laminated on an upper stage, and (ii) an improvement in a packaging density, and which is excellent in a heat radiation characteristic.

In order to achieve the object, a semiconductor device of the present invention is a semiconductor device including, on a first circuit board thereof, at least one semiconductor element, including: a second circuit board, which is (i) a connection use circuit board including an external terminal connecting portion, and (ii) mounted on an upper surface of an uppermost semiconductor element; and an electrically conductive terminal for connecting a lower surface of the second circuit board with an upper surface of the first circuit board, a space being sealed with a sealing resin between the first circuit board and the second circuit board.

In the configuration, the connection use circuit board (second circuit board) including the external terminal connecting portion is mounted on the semiconductor element. The lower surface of the connection use circuit board and the upper surface of the first circuit board are connected by the electrically conductive terminal. With this configuration, it is possible to form, on the connection use circuit board instead of the first circuit board, the wiring for providing an electrical connection between the semiconductor device and a semiconductor device being laminated on top of the connection use circuit board. This prevents the wiring of the first circuit board and the second circuit board (connection use circuit board) from being complicated, and thus restrains an increase in a planar dimension of the both substrates.

Further, the lower surface of the connection use circuit board and the upper surface of the first circuit board are combined with each other by using the electrically conductive terminal in a shape of a terminal, instead of using the wire bonding technique. Accordingly, a height of a wire loop on the connection use circuit board and that of sealing resin for sealing the wiring are not necessary, each of which height being needed in the case of performing the wire bonding technique. Thus, it is possible to reduce the size and the thickness of a semiconductor device.

Further, in the semiconductor device, the lower surface of the connection use circuit board and the upper surface of the first circuit board are electrically connected with each other via the electrically conductive terminal. Therefore, the connection use circuit board is not limited to one whose planar dimension is smaller than that of the semiconductor element located below the connection use circuit board. As such, it is possible to adopt, as the connection use circuit board, a substrate whose area is substantially the same as that of the first circuit board. This allows an increase in a plane region of the connection use circuit board, the plane region for carrying thereon the external terminal connecting portion.

Further, in order to achieve the foregoing object, a lamination of semiconductor device of the present invention includes: (i) a first semiconductor device; said first semiconductor device including: (i-1) at least one semiconductor element on a first circuit board, (i-2) a second circuit board, which is (i) a connection use circuit board including an external terminal connecting portion, and (ii) mounted on an upper surface of an uppermost semiconductor element, and (i-3) an electrically conductive terminal for connecting a lower surface of the second circuit board with an upper surface of the first circuit board, the first circuit board and the second circuit board being sealed therebetween by a sealing resin, (ii) a second semiconductor device or an electronic component laminated above the first semiconductor device; and (iii) an external connection terminal for connecting, with the external terminal connecting portion of the first semiconductor device, the second semiconductor device or the electronic component provided above the first semiconductor device.

In the configuration, another semiconductor device or an electronic component is laminated and mounted on the first semiconductor device. This configuration, while maintaining the required packaging density, solves the problem of manufacturing method and the reliability, and realizes a versatile semiconductor device.

Further, a heat generated in an operation of the upper semiconductor device (or an electronic component) is also transferred to a mounting board, via the connection use circuit board, electrically conductive terminal, the first circuit board, and the external connection terminal of the lower semiconductor device. This configuration allows an improvement in a heat radiating characteristic of a semiconductor device or an electronic component laminated on the upper stage.

Further, in order to achieve the foregoing object, a method of the present invention for manufacturing a semiconductor device includes the steps of: mounting a semiconductor element on a first circuit board, and electrically connecting the semiconductor element with the first circuit board; mounting an electronically conductive terminal on the first circuit board; mounting a second circuit board, which is a connection use circuit board including an external terminal connecting portion, on the semiconductor element, and connecting, with a lower surface of the second circuit board, the electrically conductive terminal provided on the first circuit board; sealing, with a resin, between the first circuit board and the second circuit board; and mounting an external connection terminal on a lower surface of the first circuit board.

Further, in order to achieve the foregoing object, a method of the present invention for manufacturing semiconductor devices includes the steps of: mounting a plurality of semiconductor elements on a first circuit board which is capable of carrying a plurality of semiconductor elements, and electrically connecting the semiconductor elements with the first circuit board; mounting a plurality of electrically conductive terminals on the first circuit board; mounting a second circuit board, which is a connection use circuit board including a plurality of external terminal connecting portions, on the semiconductor elements, and connecting the lower surface of the second circuit board with the electrically conductive terminals provided on the first circuit board; sealing a space with a resin between the first circuit board and the second circuit board; mounting a plurality of external connection terminals on a lower surface of the first circuit board; and cutting out each of the semiconductor devices.

The method allows manufacturing of a semiconductor device having aforementioned features.

Further, in the method, a plurality of semiconductor devices are simultaneously formed by using (i) the first circuit board corresponding to a plurality of the semiconductor devices, and (ii) the connection use circuit board. In this manufacturing method, a mold for use in the resin sealing process is not necessary. Further, the manufacturing method is capable of corresponding to manufacturing a semiconductor device of an arbitrary size. As a result, it is possible to reduce the cost.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is an embodiment of the present invention, and is a cross sectional view illustrating a configuration of a semiconductor device of Embodiment 1.

FIG. 2 is a cross sectional view illustrating an alternative form of the semiconductor device of Embodiment 1.

FIG. 3 is a cross sectional view illustrating another alternative form of the semiconductor device of Embodiment 1.

FIG. 4 is a cross sectional view illustrating yet another alternative form of the semiconductor device of Embodiment 1.

FIG. 5 is a cross sectional view illustrating a configuration of a semiconductor device of Embodiment 2.

FIG. 6 is a cross sectional view illustrating an alternative form of the semiconductor device of Embodiment 2.

FIG. 7 is a cross sectional view illustrating another alternative form of the semiconductor device of Embodiment 3.

FIG. 8(a) to FIG. 8(d) are cross sectional views illustrating a process of manufacturing a semiconductor device of Embodiment 4.

FIG. 9(a) to FIG. 9(e) are cross sectional views illustrating an alternative form of the process of manufacturing a semiconductor device of Embodiment 4.

FIG. 10 is a cross sectional view illustrating a configuration of a conventional semiconductor device.

FIG. 11 is a cross sectional view illustrating a configuration of a lamination in which a plurality of semiconductor devices of FIG. 10 are laminated.

FIG. 12 is a cross sectional view illustrating a configuration of another conventional semiconductor device.

### DESCRIPTION OF THE EMBODIMENTS

The following describes embodiments of the present invention, with reference to attached drawings.

Note that the following embodiments are no more than a concrete example of the present invention, and the technical scope of the present invention is not to be limited to the following embodiments.

### Embodiment 1

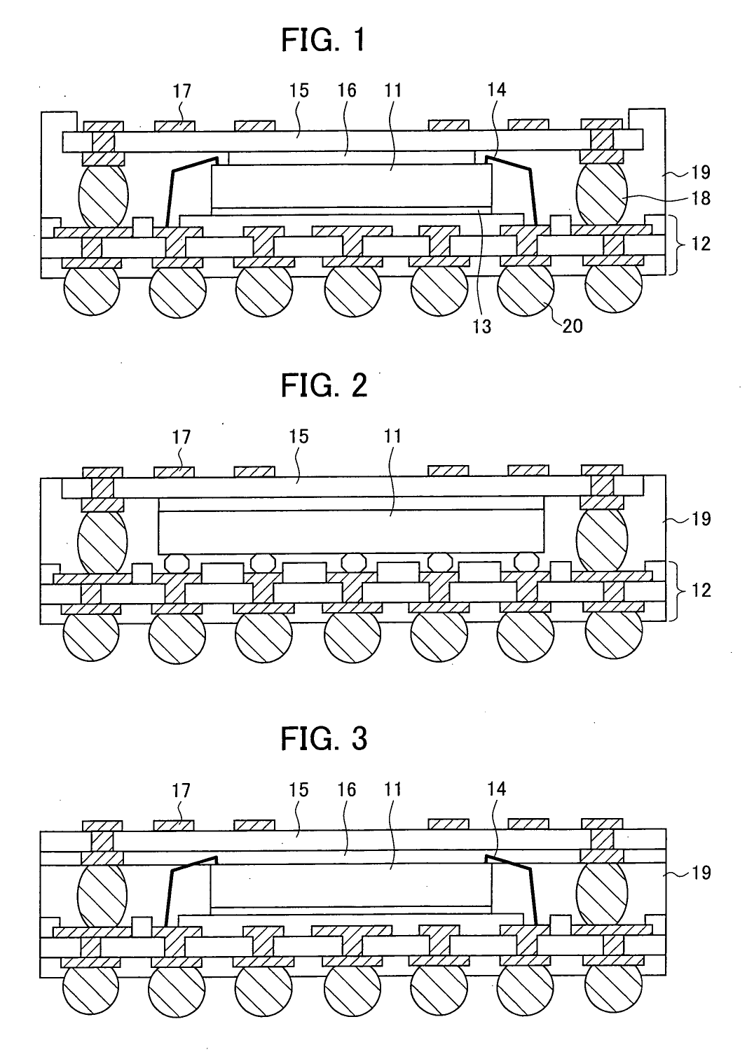

FIG. 1 illustrates a configuration of a semiconductor device of Embodiment 1, in accordance with the present invention.

As illustrated in FIG. 1, in the semiconductor device, a semiconductor element 11 and a circuit board 12 are combined with each other, interposing therebetween an adhesive material 13. The semiconductor element 11 is electrically connected with the circuit board 12 via wiring 14.

Further, a connection use circuit board 15 having an external terminal connecting portion 17 is combined with the semiconductor element 11, interposing an adhesive material 16 between the connection use circuit board 15 and the semiconductor element 11. A lower surface of the connection use circuit board 15 is electrically connected with an upper surface of the semiconductor element 11 via an electrically conductive terminal 18. The electrically conductive terminal 18 may be: a solder terminal, a metal bump, electrically conductive paste, or electrically conductive resin. In a case of using the electrically conductive past or the electrically conductive resin, the electrically conductive terminal 18 can be formed by (i) carrying out, by using a mask, a printing process with respect to the circuit board 12, or (ii) applying the electrically conductive past or the electrically conductive resin with a use of a dispenser for ejecting the electrically conductive past or the electrically conductive resin.

When using the solder terminal or the metal bump for the electrically conductive terminal 18, the height of the electrically conductive terminal 18 is kept constant due to high elasticity of the solder terminal or the metal bump. Meanwhile, the use of the electrically conductive past or the electrically conductive resin for the electrically conductive terminal 18 has the following advantages. Namely, these materials are soft before the materials are cured. Therefore, after the electrically conductive past or resin is applied to or mounted on the circuit board 12, the material can easily be deformed by a pressure applied thereto when the connection use circuit board 15 is mounted onto the semiconductor element 11. As such, it is easy to obtain a electrically conductive terminal 18 having a targeted height and shape.

In the semiconductor device, sealing resin 19 seals a space between the circuit board 12 and the connection use circuit board 15; i.e., the semiconductor element 11, the wiring 14, and the electrically conductive terminal 18, each of which being interposed between the circuit board 12 and the connection use circuit board 15. This sealing resin 19 further seals the semiconductor device, so that the external terminal connecting portion 17 and a part of the connection use circuit board 15 are exposed. The circuit board 12 is provided on its lower surface with an external connection terminal 20 which is made of an electrically conductive material. This external connection terminal 20 is used for connecting the semiconductor device with the mounting board.

In the configuration of the semiconductor device, the connection use circuit board 15 which includes the external terminal connecting portion 17 is mounted on the semiconductor element 11, interposing the adhesive material 16 between the connection use circuit board 15 and the semiconductor element 11. The lower surface of the connection use circuit board 15 and the upper surface of the circuit board 12 are connected with each other via the electrically conductive terminal 18. With this configuration, it is possible to form, on the connection use circuit board 15 instead of the circuit board 12, the wiring for providing an electrical connection between the semiconductor device of FIG. 1 and a semiconductor device being laminated on top of the connection use circuit board 15. This prevents the wiring of the circuit board 12 and the connection use circuit board 15 from being complicated, and thus restrains an increase in a planar dimension of the both substrates.

Further, the lower surface of the connection use circuit board 15 and the upper surface of the circuit board 12 are combined with each other by using the electrically conductive terminal 18 in a shape of a terminal, instead of using the wire bonding technique. Accordingly, a height of a wire loop on the connection use circuit board 15 and that of sealing resin for sealing the wiring are not necessary, each of which height being needed in the case of performing the wire bonding technique. Thus, it is possible to reduce the size and the thickness of a semiconductor device.

Further, in the semiconductor device, the lower surface of the connection use circuit board 15 and the upper surface of the circuit board 12 are electrically connected with each other via the electrically conductive terminal 18. Therefore, the connection use circuit board 15 is not limited to one whose planar dimension is smaller than that of the semiconductor element 11 located below the connection use circuit board 15. As such, it is possible to adopt, as the connection use circuit board 15, a substrate whose area is substantially the same as that of the circuit board 12. This allows an increase in a plane region of the connection use circuit board 15, the plane region for carrying thereon the external terminal connecting portion 17.

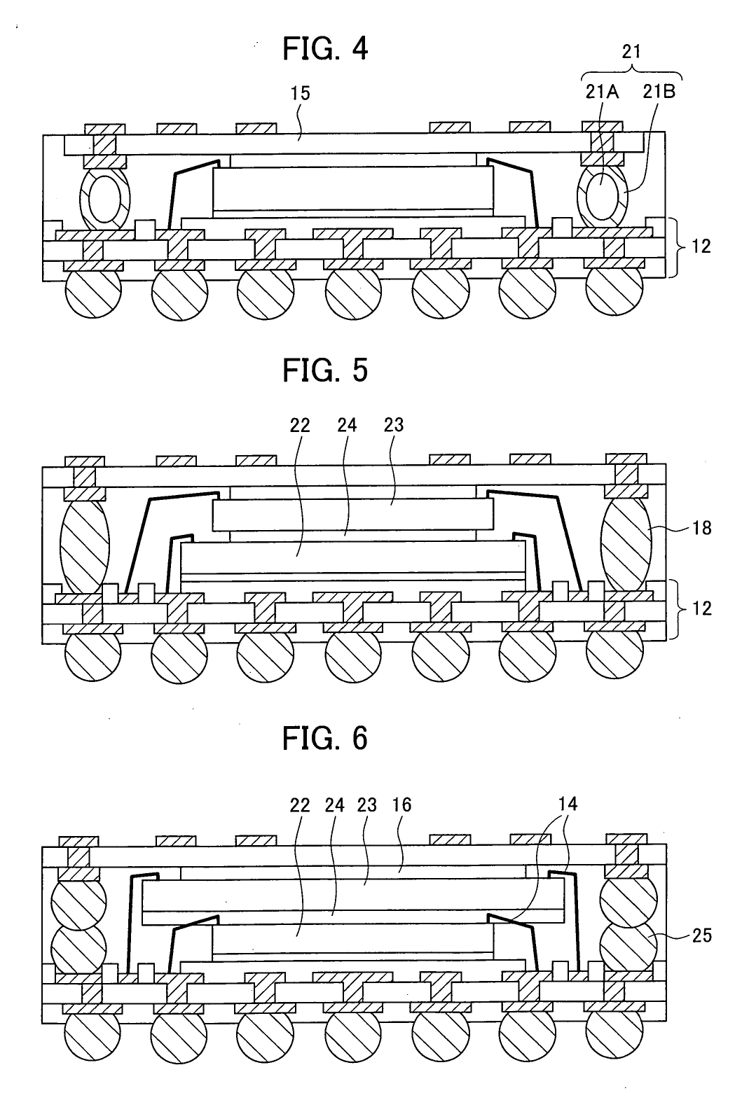

The following describes alternative forms of the semiconductor device of the present invention, with reference to FIG. 2 and FIG. 4.

In the semiconductor device illustrated in FIG. 1, the sealing resin 19 is so formed as to partially cover the upper surface of the connection use circuit board 15. The present invention however is not limited to this. For example, as illustrated in FIG. 2, the sealing resin 19 may be formed so as to cover only the bottom and side surfaces of the connection use circuit board 15, and to leave the entire upper surface of the connection use circuit board 15 uncovered by the sealing resin 19. Alternatively, as illustrated in FIG. 3, the sealing resin 19 may be so formed that the entire upper surface and at least a part of the side surfaces of the connection use circuit board 15 are exposed. By exposing the entire upper surface of the connection use circuit board 15, the external terminal connecting portion 17 can be arranged allover the connection use circuit board 15.

Further, in the semiconductor device illustrated in FIG. 1, the semiconductor element 11 and the circuit board 12 are connected with each other by using a wire bonding technique. However, the present invention is not limited to this, and the semiconductor element 11 and the circuit board 12 may be connected with each other by using a flip-chip bonding technique illustrated in FIG. 2 or electrically conductive resin. A use of a flip-chip bonding technique for connecting the semiconductor element 11 with the circuit board 12 is advantageous in reducing a package height.

Further, in the semiconductor device illustrated in FIG. 1, the adhesive material 16 is applied only to the semiconductor element 11. However, the present invention is not limited to this, and the adhesive material 16 may be applied to the entire lower surface of the connection use circuit board 15 as illustrated in FIG. 3. In this case, the wiring 14 may partially be covered by the adhesive material 16.

A semiconductor device illustrated in FIG. 4 includes an electrically conductive terminal 21 instead of the electrically conductive terminal 18 of the semiconductor device illustrated in FIG. 1. The electrically conductive terminal 21 includes: a core 21A; and a electrically conductive layer 21B outside the core 21A. The core 21A may be an electrically conductive material or an insulative material. Such a core 21A is made of metal or resin.

In the semiconductor device, the core 21A of the electrically conductive terminal 21 allows the height of the electrically conductive terminal 21 to be kept constant, thereby maintaining a connection stability between the connection use circuit board 15 and the circuit board 12. A use of the core 21A which is harder than the electronically conductive layer 21B outside the core 21A is advantageous in terms of maintaining the height of the electronically conductive terminal 21. This is particularly true when a high-temperature process is carried out in manufacturing of the semiconductor device of the present embodiment. Note that the hardness in this specification is expressed, for example, in hardness degree, Young's modulus, or elastic modulus.

### Embodiment 2

The following describes, with reference to FIG. 5, a semiconductor device of Embodiment 2 in accordance with the present invention.

As illustrated in FIG. 5, the semiconductor device of Embodiment 2 includes a plurality of semiconductor elements 22 and 23 on a circuit board 12. A connection use circuit board 15 is mounted on an uppermost semiconductor element, interposing therebetween an adhesive material 16. That is, the connection use circuit board 15 is mounted on the semiconductor 23 which is mounted on an upper stage, and which is farthest in distance from the circuit board 12. Further, the semiconductor element 22 on a lower stage and the semiconductor element 23 on the upper stage are connected with each other by using an adhesive material 24. As described, the laminating of a plurality of semiconductor element for mounting the plurality of semiconductor elements in a single semiconductor device improves the packaging density of the semiconductor device. Needless to mention that the number of semiconductor elements to be mounted in a semiconductor device may be three or more.

Note that, in the semiconductor device illustrated in FIG. 5, the semiconductor element 22 mounted on the lower stage is larger in size than the semiconductor element 23 mounted on the upper stage. However, the present invention is not limited to this. That is, an upper semiconductor element may have the same size as that of a lower semiconductor element. Alternatively, it is possible to provide a semiconductor element whose size is remarkably larger than that of the semiconductor element on the lower stage. It is also possible to mount, by laminating, plural semiconductor elements whose respective sizes are at all the same. Note that a combination of semiconductor elements is regulated by size of each semiconductor element, and/or a positional relationship of wire-bonding pad of each semiconductor element.

FIG. 6 illustrates a configuration of an example where the semiconductor element 23 on the upper stage is larger than the semiconductor element 22 of the lower stage. At this point, wiring 14 which connects the lower semiconductor element 22 with the circuit board 12 is partially covered by the adhesive agent 24, so that the upper semiconductor element 23 and the wiring 14 are insulated from each other. Further, in the configuration of FIG. 6, the wiring 14 of the other semiconductor element 23 is not covered. This wiring 14 of the semiconductor element 23 may also be partially covered by the adhesive material 16.

By covering the wiring 14 with the adhesive material 24 or 16, the combination of the semiconductor elements to be mounted in the semiconductor device of the present embodiment is no longer limited, and various types of semiconductor elements can be mounted in a single semiconductor device. This realizes a small semiconductor device which is thinner and more sophisticated.

Further, in the case of mounting, by laminating, plural semiconductor elements in a single semiconductor device, a distance between the circuit board 12 and the connection use circuit board 15 increases, when compared to a case of mounting only one semiconductor element. In this case, as illustrated in FIG. 6, an electrically conductive terminal which connects the circuit board 12 and the connection use circuit board 15 may include a plurality of substantially spherical electrically conductive terminals 25. This configuration, in which the substantially spherical electrically conductive terminals 25 are laminated, allows an easier adjustment of the height of the electrically conductive material for connecting the circuit board 12 with the connection use circuit board 15.

More specifically, as illustrated in FIG. 5, the electrically conductive terminal 18 will have a shape having a lengthwise direction (e.g. ellipsoidal shape), if only one electrically conductive terminal 18 is arranged in a thickness direction of the semiconductor device (i.e., in a lamination direction of substrates or elements), for connecting the circuit board 12 with the connection use circuit board 15. In this case, the electrically conductive terminal 18 needs to be mounted so that its lengthwise direction is perpendicular to a normal line of the substrate. This causes difficulties in a height adjustment of the electrically conductive terminal 18.

Note that the effect, which allows an easier adjustment of the height of the electrically conductive material for connecting the circuit board 12 with the connection use circuit board 15, is not limited to the case where a plurality of semiconductor elements are laminated in a single semiconductor device. By laminating the plurality of substantially spherical electrically conductive terminals 25 as illustrated in FIG. 6, the same effect is also obtained in other cases as well. For Such electrically conductive terminals 25, suitably used are a solder ball or a terminal having an electrically conductive layer outside a core of the terminal.

### Embodiment 3

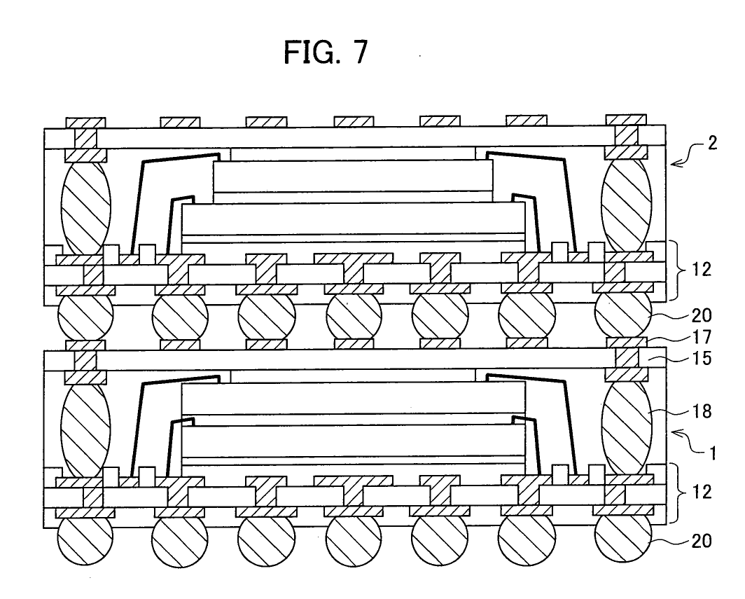

The following describes, with reference to FIG. 7, a configuration of a semiconductor device of Embodiment 3 in accordance with the present invention. FIG. 7 illustrates an exemplary configuration of a lamination in which a plurality of the semiconductor devices of Embodiment 1 and/or Embodiment 2 are laminated. This lamination serves as a single semiconductor device.

More specifically, the semiconductor devices 1 and 2 are laminated in the semiconductor device of FIG. 7, and an external terminal connecting portion 17 of a connection use circuit board 15 in a lower semiconductor device 1 is connected with an external connection terminal 20 of an external connection portion of a circuit board 12 in an upper semiconductor device 2. Thus, the lower semiconductor device 1 and the upper semiconductor device 2 are electrically connected with each other, thereby forming a lamination of semiconductor devices.

Note that, in the above described configuration in which the plurality of the semiconductor devices are laminated, it is not necessary that both of the upper and the lower semiconductor devices be the semiconductor device of the present invention, provided that at least the lower semiconductor device is the semiconductor device of the present invention. Note further that, a member to be laminated on the upper stage may be an electronic component other than a semiconductor device.

In the semiconductor device of Embodiment 3, a heat generated in an operation of the upper semiconductor device 2 (or an electronic component) is also transferred to a mounting board, via the connection use circuit board 15, electrically conductive terminal 18, the circuit board 12, and the external connection terminal 20 of the lower semiconductor device 1.

With the use of the electrically conductive terminal 18 for connecting the connection use circuit board 15 with the circuit board 12, the semiconductor device or the electronic component on the upper stage has a better heat radiating characteristic than a case of using wire bonding technique for connecting the connection use circuit board 15 with the circuit board 12. This is attributed to a larger cross sectional area of the electrically conductive terminal 18 than wiring, and to a shortened path for transferring the heat.

### Embodiment 4

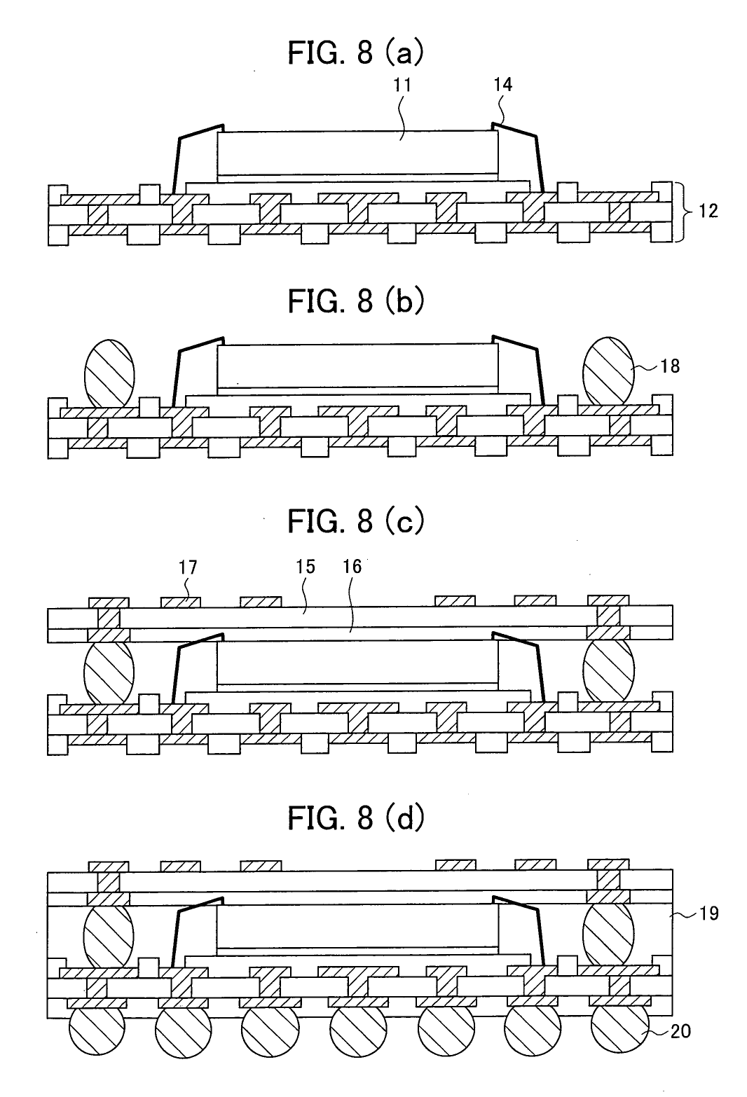

The following describes, with reference to FIG. 8(a) to FIG. 8(d), a method of manufacturing a semiconductor device of the present invention. Note that FIG. 8(a) to FIG. 8(d) illustrates, as an example, a case of manufacturing the semiconductor device illustrated in FIG. 3.

Firstly, as illustrated in FIG. 8(a), a semiconductor element 11 is mounted on a circuit board 12, and the semiconductor element 11 and the circuit board 12 are connected with each other by using wiring 14.

Next, as illustrated in FIG. 8(b), an electrically conductive terminal 18 is mounted on the circuit board 12. Then, as illustrated in FIG. 8(c), a connection use circuit board 15, to which an adhesive material 16 has been applied beforehand, is adhered to the semiconductor element 11. On the connection use circuit board 15, an external terminal connecting portion 17 has been formed in advance. In the process of combining the semiconductor element 11 with the connection use circuit board 15 by using the adhesive material 16, a heat used in the process may be used for combining, at the same time, the electrically conductive terminal 18 with the connection use circuit board 15.

The heat applied at the time of combining causes a material of the electrically conductive terminal 18 to be softened, molten, or to become a closer status to these, thereby lowering a hardness degree or an elasticity of the material. By applying a pressure from above for connecting the connection use circuit board 15, a height of the electrically conductive terminal 18 is controlled while combining the connection use circuit board 15 with the electrically conductive terminal 18.

Further, a process of combining the connection use circuit board 15 with the electrically conductive terminal 18 may be carried out after the connection use circuit board 15 and the semiconductor element 11 are combined with each other.

At last, as illustrated in FIG. 8(d), a sealing resin 19 is injected for sealing, and the external connection terminal 20 is mounted.

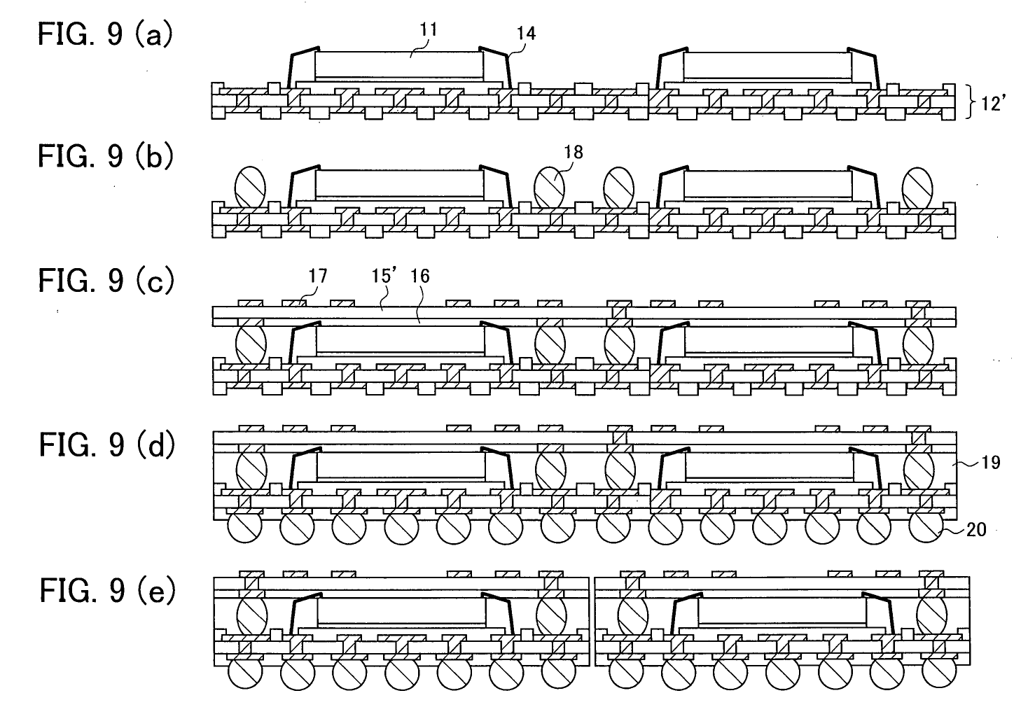

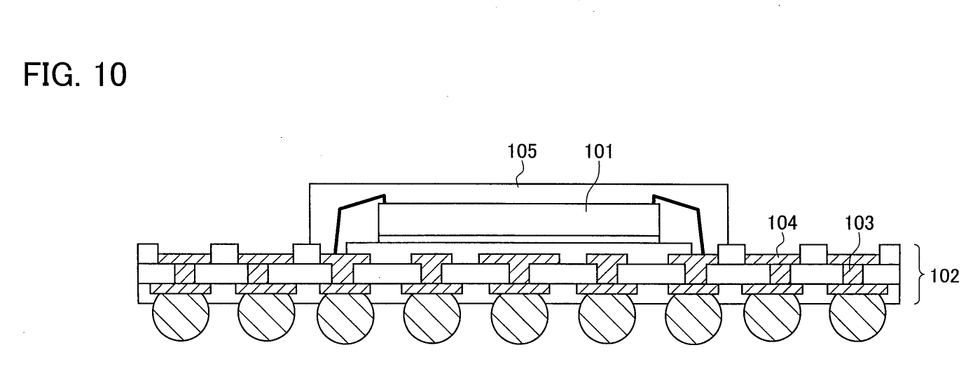

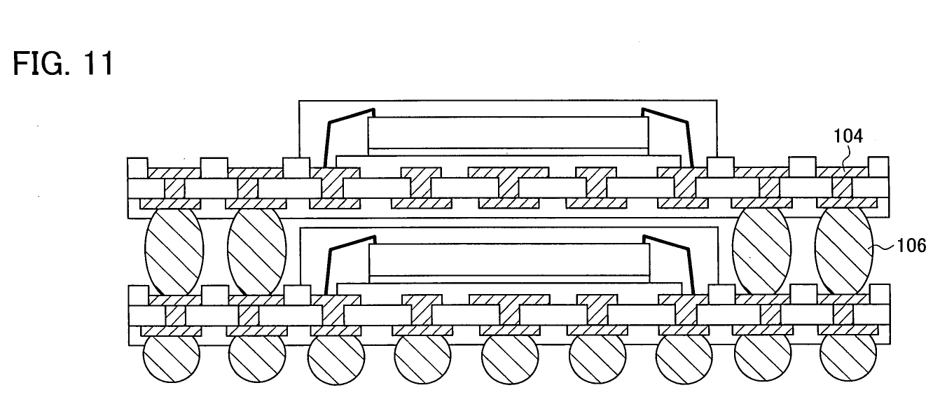

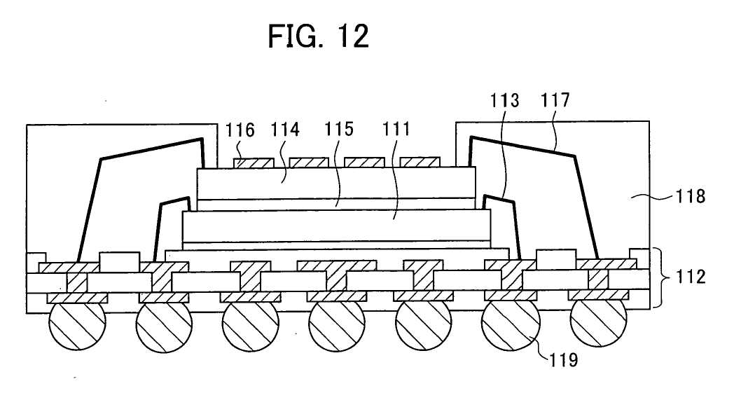

Note that the above description with reference to FIG. 8(a) to FIG. 8(d) deal with the case of manufacturing a single semiconductor device. However, all the processes illustrated in FIG. 8(a) to FIG. 8(d) are also applicable to a manufacturing method (See FIG. 9(a) to FIG. 9(e)) in which (I) a plurality of semiconductor devices are manufactured by using a circuit board 12′ and a connection use circuit board 15′, each corresponding to a plurality of the semiconductor devices, and then (II) each of the semiconductor devices are cut out.

In this manufacturing method, a mold for use in the resin sealing process is not necessary. Further, the manufacturing method is capable of corresponding to manufacturing a semiconductor device of an arbitrary size. As a result, it is possible to reduce the cost.

As described a semiconductor device of the present invention is a semiconductor device including, on a first circuit board thereof, at least one semiconductor element, including: a second circuit board, which is (i) a connection use circuit board including an external terminal connecting portion, and (ii) mounted on an upper surface of an uppermost semiconductor element; and an electrically conductive terminal for connecting a lower surface of the second circuit board with an upper surface of the first circuit board, a space being sealed with a sealing resin between the first circuit board and the second circuit board.

In the configuration, the connection use circuit board (second circuit board) including the external terminal connecting portion is mounted on the semiconductor element. The lower surface of the connection use circuit board and the upper surface of the first circuit board are connected by the electrically conductive terminal. With this configuration, it is possible to form, on the connection use circuit board instead of the first circuit board, the wiring for providing an electrical connection between the semiconductor device and a semiconductor device being laminated on top of the connection use circuit board. This prevents the wiring of the first circuit board and the second circuit board (connection use circuit board) from being complicated, and thus restrains an increase in a planar dimension of the both substrates.

Further, the lower surface of the connection use circuit board and the upper surface of the first circuit board are combined with each other by using the electrically conductive terminal in a shape of a terminal, instead of using the wire bonding technique. Accordingly, a height of a wire loop on the connection use circuit board and that of sealing resin for sealing the wiring are not necessary, each of which height being needed in the case of performing the wire bonding technique. Thus, it is possible to reduce the size and the thickness of a semiconductor device.

Further, in the semiconductor device, the lower surface of the connection use circuit board and the upper surface of the first circuit board are electrically connected with each other via the electrically conductive terminal. Therefore, the connection use circuit board is not limited to one whose planar dimension is smaller than that of the semiconductor element located below the connection use circuit board. As such, it is possible to adopt, as the connection use circuit board, a substrate whose area is substantially the same as that of the first circuit board. This allows an increase in a plane region of the connection use circuit board, the plane region for carrying thereon the external terminal connecting portion.

Further, the semiconductor device of the present invention may be adapted so that the electrically conductive terminal is a terminal including an electrically conductive layer provided around a core.

In the configuration, the provision of the core to the electrically conductive terminal allows the height of the electrically conductive terminal to be kept constant, thereby maintaining a connection stability between the connection use circuit board and the first circuit board.

Further, the semiconductor device of the present invention may be adapted so that the electrically conductive terminal is arranged such that a plurality of substantially spherical electrically conductive terminals are laminated in a thickness direction of the semiconductor device.

The configuration allows an easier adjustment of the height of the electrically conductive material which connects the first circuit board with the connection use circuit board. This is advantageous in a case where a distance between the first circuit board and the connection use circuit board is long.

Further, the semiconductor device of the present invention may further include: the first circuit board includes a plurality of semiconductor elements thereon.

As described, the laminating of a plurality of semiconductor elements for mounting the plurality of semiconductor elements in a single semiconductor device improves the packaging density of the semiconductor device.

Further, a s lamination of semiconductor device of the present invention includes: (i) a first semiconductor device; said first semiconductor device including: (i-1) at least one semiconductor element on a first circuit board, (i-2) a second circuit board, which is (i) a connection use circuit board including an external terminal connecting portion, and (ii) mounted on an upper surface of an uppermost semiconductor element, and (i-3) an electrically conductive terminal for connecting a lower surface of the second circuit board with an upper surface of the first circuit board, the first circuit board and the second circuit board being sealed therebetween by a sealing resin, (ii) a second semiconductor device or an electronic component laminated above the first semiconductor device; and (iii) an external connection terminal for connecting, with the external terminal connecting portion of the first semiconductor device, the second semiconductor device or the electronic component provided above the first semiconductor device.

In the configuration, another semiconductor device or an electronic component is laminated and mounted on the first semiconductor device. This configuration, while maintaining the required packaging density, solves the problem of manufacturing method and the reliability, and realizes a versatile semiconductor device.

Further, a heat generated in an operation of the upper semiconductor device (or an electronic component) is also transferred to a mounting board, via the connection use circuit board, electrically conductive terminal, the first circuit board, and the external connection terminal of the lower semiconductor device. This configuration allows an improvement in a heat radiating characteristic of a semiconductor device or an electronic component laminated on the upper stage.

Further, as described, a method of the present invention for manufacturing a semiconductor device includes the steps of: mounting a semiconductor element on a first circuit board, and electrically connecting the semiconductor element with the first circuit board; mounting an electronically conductive terminal on the first circuit board; mounting a second circuit board, which is a connection use circuit board including an external terminal connecting portion, on the semiconductor element, and connecting, with a lower surface of the second circuit board, the electrically conductive terminal provided on the first circuit board; sealing, with a resin, between the first circuit board and the second circuit board; and mounting an external connection terminal on a lower surface of the first circuit board.

Further, as described, a method of the present invention for manufacturing semiconductor devices includes the steps of: mounting a plurality of semiconductor elements on a first circuit board which is capable of carrying a plurality of semiconductor elements, and electrically connecting the semiconductor elements with the first circuit board; mounting a plurality of electrically conductive terminals on the first circuit board; mounting a second circuit board, which is a connection use circuit board including a plurality of external terminal connecting portions, on the semiconductor elements, and connecting the lower surface of the second circuit board with the electrically conductive terminals provided on the first circuit board; sealing a space with a resin between the first circuit board and the second circuit board; mounting a plurality of external connection terminals on a lower surface of the first circuit board; and cutting out each of the semiconductor devices.

The method allows manufacturing of a semiconductor device having aforementioned features.

Further, in the method, a plurality of semiconductor devices are simultaneously formed by using (i) the first circuit board corresponding to a plurality of the semiconductor devices, and (ii) the connection use circuit board. In this manufacturing method, a mold for use in the resin sealing process is not necessary. Further, the manufacturing method is capable of corresponding to manufacturing a semiconductor device of an arbitrary size. As a result, it is possible to reduce the cost.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A semiconductor device including, on a first circuit board thereof, at least one semiconductor element, comprising:
a second circuit board, which is (i) a connection use circuit board including an external terminal connecting portion, and (ii) mounted on an upper surface of an uppermost semiconductor element; and
an electrically conductive terminal for connecting a lower surface of the second circuit board with an upper surface of the first circuit board,
a space being sealed with a sealing resin between the first circuit board and the second circuit board.

2. The semiconductor device as set forth in claim 1, wherein
the electrically conductive terminal is a terminal including an electrically conductive layer provided around a core.

3. The semiconductor device as set forth in claim 1, wherein
the electrically conductive terminal is arranged such that a plurality of substantially spherical electrically conductive terminals are laminated in a thickness direction of the semiconductor device.

4. The semiconductor device as set forth in claim 1, further comprising
the first circuit board includes a plurality of semiconductor elements thereon.

5. A lamination of semiconductor device, comprising:
(i) a first semiconductor device;
said first semiconductor device including:
(i-1) at least one semiconductor element on a first circuit board,
(i-2) a second circuit board, which is (i) a connection use circuit board including an external terminal connecting portion, and (ii) mounted on an upper surface of an uppermost semiconductor element, and
(i-3) an electrically conductive terminal for connecting a lower surface of the second circuit board with an upper surface of the first circuit board,
the first circuit board and the second circuit board being sealed therebetween by a sealing resin,
(ii) a second semiconductor device or an electronic component laminated above the first semiconductor device; and
(iii) an external connection terminal for connecting, with the external terminal connecting portion of the first semiconductor device, the second semiconductor device or the electronic component provided above the first semiconductor device.

6. A method for manufacturing a semiconductor device, comprising the steps of:
mounting a semiconductor element on a first circuit board, and electrically connecting the semiconductor element with the first circuit board;
mounting an electronically conductive terminal on the first circuit board;
mounting a second circuit board, which is a connection use circuit board including an external terminal connecting portion, on the semiconductor element, and connecting, with a lower surface of the second circuit board, the electrically conductive terminal provided on the first circuit board;
sealing, with a resin, between the first circuit board and the second circuit board; and
mounting an external connection terminal on a lower surface of the first circuit board.

7. A method for manufacturing semiconductor devices, comprising the steps of:
mounting a plurality of semiconductor elements on a first circuit board which is capable of carrying a plurality of semiconductor elements, and electrically connecting the semiconductor elements with the first circuit board;
mounting a plurality of electrically conductive terminals on the first circuit board;
mounting a second circuit board, which is a connection use circuit board including a plurality of external terminal connecting portions, on the semiconductor elements, and connecting the lower surface of the second circuit board with the electrically conductive terminals provided on the first circuit board;
sealing a space with a resin between the first circuit board and the second circuit board;
mounting a plurality of external connection terminals on a lower surface of the first circuit board; and
cutting out each of the semiconductor devices.
